(19) United States
(12) Patent Application Publication
(10) Pub. No.: US 2010/0123243 A1
(43) Pub. Date: May 20, 2010

(54) FLIP-CHIP CHIP-SCALE PACKAGE STRUCTURE

(75) Inventor: CHUNG HSING TZU, TAIPEI COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: GREAT TEAM BACKEND FOUNDRY, INC., TORTOLA (VG)

(21) Appl. No.: 12/358,627

(22) Filed: Jan. 23, 2009

Related U.S. Application Data
(60) Provisional application No. 61/115,519, filed on Nov. 17, 2008.

(51) Int. Cl. H01L 23/498

(52) U.S. Cl. 257/737; 257/E23.068

(57) ABSTRACT

The present invention relates to a flip-chip chip-scale package structure, and more particularly to a flip-chip chip-scale package structure with high thermal and electrical performance. The flip-chip chip-scale package structure comprising: a die, a substrate, and a metal ribbon. The die comprises a back-side metal and a plurality of bond pads. The die is bonded to the substrate by a plurality of bumps. The metal ribbon is bonded to the back-side metal by way of metal diffusion bonding. By using the package structure of the present invention, it provides high thermal and electrical performance for semiconductor devices.

### CROSS REFERENCE TO RELATED APPLICATIONS

This application claims priority of U.S. Provisional Application No. 61/115,519 filed on 17 Nov. 2008 under 35 U.S.C. §119(e), the entire contents of which are all hereby incorporated by reference.

### FIELD OF THE INVENTION

The present invention relates to a flip-chip chip-scale package structure, and more particularly to a flip-chip chip-scale package structure with high thermal and electrical performance.

### BACKGROUND OF THE INVENTION

FIG. 1 is a cross-sectional view of a power transistor with flip-chip package structure in accordance with a prior art. The typical package structure of a power transistor 10 comprises a die 14, a substrate or lead frame 12, and a metal cap 16.

The die 14 comprises a plurality of bond pads 141 formed on the bottom surface, and a back-side metal 143 formed on the top surface. A plurality of bumps 145 is formed on the bond pads 141. The die 14 is bonded to the substrate or lead frame 12 by the bumps 145.

One end 161 of the metal cap 16 is attached to the back-side metal 143, and the other end 163 of the metal cap 16 is attached to the substrate or lead-frame 12. Both the ends 161 and 163 are bonded to the back-side metal 143 and the substrate or lead frame 12 by solder or conductive adhesive 147 and 167.

Voids often occur in the solder or conductive adhesive 147 and 167 while bonding the metal cap 16 to the back-side metal 143, or the substrate 12, or encapsulated the die 14 and the metal cap 16 with a molding compound 18. The voids in the solder or conductive adhesive 147 and 167 will reduce the thermal performance and electrical performance of the device.

FIG. 2 is a cross-sectional view of a power transistor with a quad flat no-lead (QFN) package structure in accordance with a prior art. The typical package structure of a power transistor 20 with a QFN package structure comprising a die 24 and a lead-frame 22 with a plurality of leads 221, 223, 221.

The die 24 is bonded to the lead 223 of the lead-frame 22 by a jointing material 227, such as a solder. There are bond pads 241, 243 formed on the top surface of the die 24. Bonding wires 261, 263 are bonded to the bond pads 241, 243 in one end respectively, and bonded to the leads 221, 225 of the lead frame 22 in the other end respectively. Then, the lead-frame 22, the die 24, and bonding wires 261, 263 are encapsulated by a molding compound 28.

The QFN package structure provides high thermal performance by way of the large contact area between the die 24 and the lead-frame 22. The electrical performance of the QFN package structure is restricted by the bonding wires 261, 263 because of a long conducting path and narrow cross-sectional area.

### SUMMARY OF THE INVENTION

It is the primary objective of the present invention to provide a flip-chip chip-scale package structure with high thermal and electrical performance.

It is a secondary objective of the present invention to provide a flip-chip chip-scale package structure, wherein the back side metal of the die is connected to the substrate or lead-frame by a metal ribbon to provide a large contact area and a large conducting cross sectional area.

It is another objective of the present invention to provide a flip-chip chip-scale package structure, wherein the metal ribbon is bonded to the back side metal of the die by metal diffusion bonding to prevent voids between the metal ribbon and the back-side metal of the die.

It is another objective of the present invention is to provide a flip-chip chip-scale package structure, wherein the metal ribbon is bonded to the substrate or lead frame by metal diffusion bonding to prevent voids between the metal ribbon and the substrate or lead-frame.

It is another objective of the present invention is to provide a flip-chip chip-scale package structure, further comprising a metal cap bonded to the metal ribbon and the back-side metal of the die to provide a higher thermal performance.

The present invention provides a flip-chip chip-scale package structure, comprising a die including a first surface and a second surface; a plurality of bond pads formed on said second surface of said die; a plurality of bumps formed on said plurality of bond pads; a substrate bonded with said die by said plurality of bumps; a back side metal formed on said first surface of said die; and a metal ribbon including a first end and a second end, wherein said first end is disposed on said back side metal, and said second end is disposed on said substrate.

The present invention further provides a chip package structure, comprising a substrate; a die including a first surface and a second surface, a plurality of bond pads formed on said second surface of said die and a plurality of bumps formed between said plurality of bond pads and the substrate; a back-side metal formed on said first surface of said die; a ribbon including a first end and a second end, wherein said first end is electrically and thermally coupled to said back-side metal, and said second end is electrically and thermally coupled to said substrate; and a cap thermally coupled to said first end of said ribbon.

### BRIEF DESCRIPTION OF THE DRAWINGS

FIG. 1 is a cross-sectional view of a power transistor with a flip-chip package structure in accordance with a prior art.

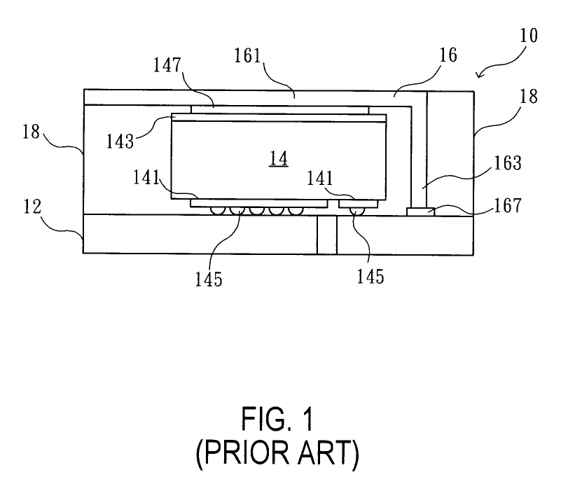

FIG. 2 is a cross-sectional view of a power transistor with a quad flat no-lead (QFN) package structure in accordance with a prior art.

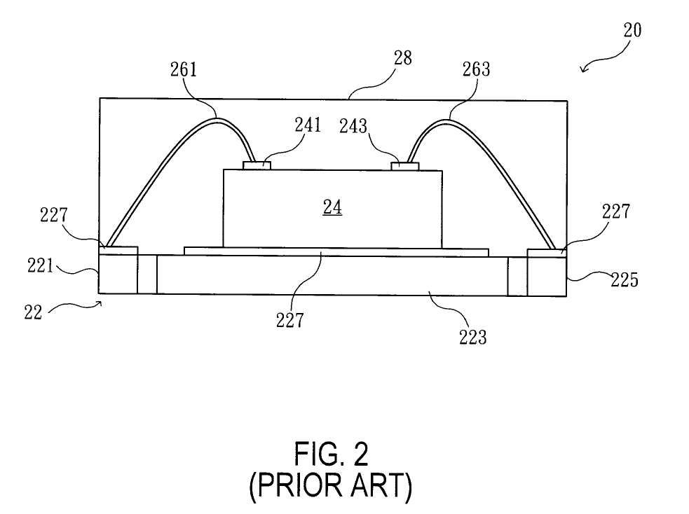

FIG. 3 is a cross sectional view of a semiconductor device with a flip-chip chip-scale package structure in accordance with an embodiment of the present invention.

FIG. 4 is a cross-sectional view of a semiconductor device with a flip-chip chip-scale package structure in accordance with another embodiment of the present invention.

FIG. 5 is a cross-sectional view of a semiconductor device with a flip-chip chip-scale package structure in accordance with another embodiment of the present invention.

FIG. 6 is a cross-sectional view of a semiconductor device with a flip-chip chip-scale package structure in accordance with still another embodiment of the present invention.

### DETAILED DESCRIPTION OF DISCLOSED EMBODIMENTS

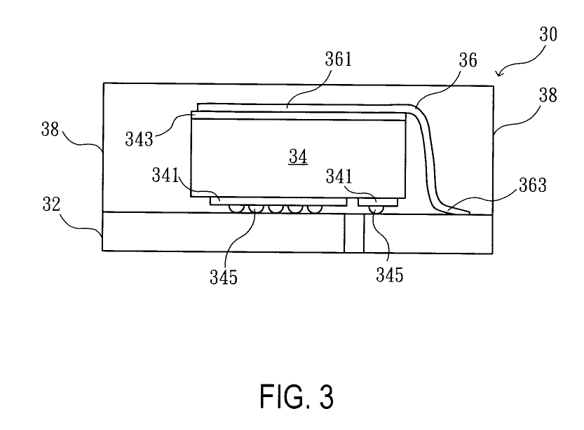

Referring to FIG. 3, there is shown a cross-sectional view of a semiconductor device with a flip-chip chip-scale package structure in accordance with an embodiment of the present invention. The semiconductor device 30, such as a power transistor, comprises a die 34, a substrate 32, and a metal ribbon 36.

The die 34 comprises a first surface and a second surface, such as a top surface and a bottom surface. There is a plurality of bond pads 341 formed on the bottom surface of the die 34. And a plurality of bumps 345 is formed on the bond pads 341 by way of metal diffusion bonding and without under bump metallurgy (UBM) between the bumps and the bond pads. The die 34 is bonded to the substrate 32 by the bumps 345 to from a flip-chip bonding.

There is a back-side metal 343 formed on the top surface of the die 34. One end 361 of the metal ribbon 36 is bonded to the back side-metal 343 of the die 34 by way of metal diffusion bonding, the other end 363 of the metal ribbon 36 is bonded to the substrate 32 by way of metal diffusion bonding to establish the electrical connection between the back-side metal 343 of the die 34 and the substrate 32. When the electrical connection is established, the thermal connection is also established. And then, the die 34, the metal ribbon 36, and the substrate 32 are encapsulated by a molding compound 38, such as an epoxy compound.

Because of the large contact area between the metal ribbon 36 and the back-side metal 343 of the die 34 and the large conducting cross-sectional area, the device's electrical performance will be much better than that of the power transistor with a QFN package structure, in accordance with the prior art. It is much easier for the heat generated by the die 34 to propagate through the metal ribbon 36 to the substrate 32, and further propagate to the system board.

In the present invention, the metal ribbon 36 is bonded to the back-side metal 343 of the die 34 by way of metal diffusion bonding. This would prevent the bonding interface of the metal ribbon 36 and the back-side metal 343 from forming voids. The electrical performance of the semiconductor device in accordance with the present invention will be much better than the power transistor with a flip-chip package structure, in accordance with the prior art.

In another embodiment of the present invention, the substrate 32 of the semiconductor device 30 can be replaced by a lead-frame, and it can provide the same thermal performance and electrical performance as the previous embodiment.

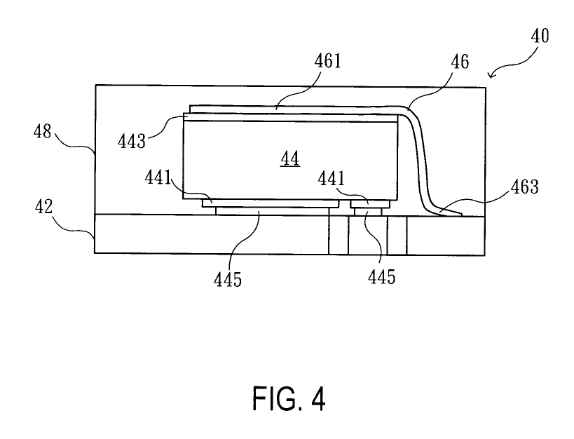

Referring to FIG. 4, there is shown a cross-sectional view of a semiconductor device with a flip-chip chip-scale package structure in accordance with another embodiment of the present invention. The semiconductor device 40, such as a power transistor, comprises a die 44, a substrate 42, and a metal ribbon 46.

The die 44 comprises a first surface and a second surface, such as a top surface and a bottom surface. There is a plurality of bond pads 441 formed on the bottom surface of the die 44. A plurality of block bumps 445 is formed on the bond pads 441 by way of metal diffusion bonding and without under bump metallurgy (UBM) between the bumps and the bond pads. The die 44 is bonded to the substrate 42 by the block bumps 445 to from a flip-chip bonding.

There is a back-side metal 443 formed on the top surface of the die 44. One end 461 of the metal ribbon 46 is disposed on the back side metal 443 of the die 44; the other end 463 of the metal ribbon 46 is disposed on the substrate 42 to establish the electrical connection between the back-side metal 443 of the die 44 and the substrate 42. When the electrical connection is established, the thermal connection is also established. Then, the die 44, the metal ribbon 46, and the substrate 42 are encapsulated by a molding compound 48, such as an epoxy compound.

Because of the large contact area between the metal ribbon 46 and the back-side metal 443 of the die 44 and the large conducting cross sectional area, the device's electrical performance will be much better than that of the power transistor with a QFN package structure in accordance with the prior art. It is much easier for the heat generated by the die 44 to propagate through the metal ribbon 46 to the substrate 42, and further propagate to the system board.

Moreover, in the present embodiment, the block bumps also provide a larger contact area for the die 44 and the substrate 42, and it would be progressive for the electrical performance and the thermal performance.

In the present invention, the metal ribbon 46 is bonded to the back-side metal 443 of the die 44 by way of metal diffusion bonding. This would prevent the bonding interface of the metal ribbon 46 and the back-side metal 443 from forming voids. The electrical performance of the semiconductor device, in accordance with the present invention, will be much better than the power transistor with a flip-chip package structure, in accordance with the prior art.

In another embodiment of the present invention, the substrate 42 of the semiconductor device 40 can be replaced by a lead frame, and it can provide the same thermal performance and electrical performance as the previous embodiment.

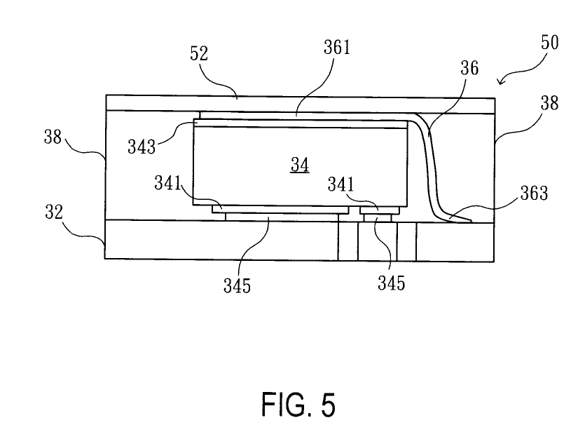

Referring to FIG. 5, there is shown a cross-sectional view of a semiconductor device with a flip-chip chip-scale package structure in accordance with another embodiment of the present invention. The semiconductor device 50 is almost the same as the embodiment shown in FIG. 3, comprising a die 34, a substrate 32, and a metal ribbon 36, but being further comprised of a metal cap 52.

The metal cap 52 is disposed on the metal ribbon 36 and the back-side metal 343 to provide for more powerful heat dissipation. The package structure of the present embodiment is provided for devices that need much higher thermal performance.

Since there is no need for the metal cap 52 to contribute to electrical performance, the metal cap 52 can be bonded to the metal ribbon 36 and the back-side metal 343 by way of metal diffusion bonding or thermal-sonic bonding, ultrasonic-compress bonding, thermal-compress bonding, or soldering.

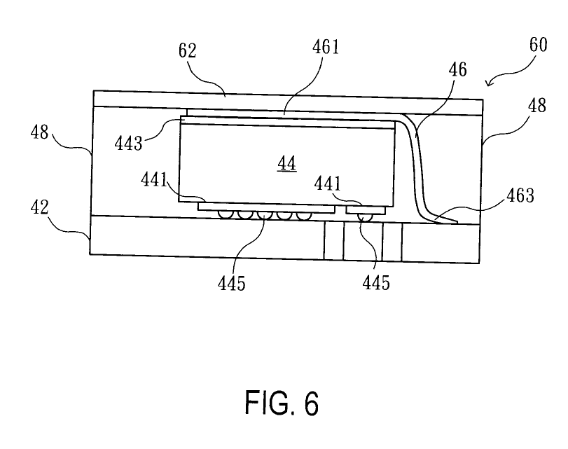

Referring to FIG. 6, there is shown a cross-sectional view of a semiconductor device with a flip-chip chip-scale package structure in accordance with another embodiment of the present invention. The semiconductor device 60 is almost the same as the embodiment shown in FIG. 4, comprising a die 44, a substrate 42, and a metal ribbon 46, but being further comprised of a metal cap 62.

The metal cap 62 is disposed on the metal ribbon 46 and the back-side metal 443 to provide for more powerful heat dissipation. The package structure of the present embodiment is provided for devices that need much higher thermal performance.

Since there is no need for the metal cap 62 to contribute to electrical performance, the metal cap 62 can be bonded to the metal ribbon 46 and the back-side metal 443 by way of metal diffusion bonding or thermal-sonic bonding, ultrasonic-compress bonding, thermal-compress bonding, or soldering.

The present invention is not limited to the above-described embodiments. Various alternatives, modifications and equivalents may be used. Therefore, the above embodiments should not be taken as limiting the scope of the invention, which is defined by the appending claims.

What is claimed is:

1. A flip-chip chip-scale package structure, comprising:
a die including a first surface and a second surface;
a plurality of bond pads formed on said second surface of said die;
a plurality of bumps formed on said plurality of bond pads;
a substrate bonded with said die by said plurality of bumps;
a back-side metal formed on said first surface of said die; and
a metal ribbon including a first end and a second end, wherein said first end is disposed on said back side metal, and said second end is disposed on said substrate.

2. The flip-chip chip-scale package structure of claim 1, wherein said first end of said metal ribbon is bonded to said back-side metal by way of metal diffusion bonding.

3. The flip-chip chip-scale package structure of claim 1, wherein said second end of said metal ribbon is bonded to said substrate by way of metal diffusion bonding.

4. The flip-chip chip-scale package structure of claim 1, further comprising a molding compound encapsulating said die and said metal ribbon.

5. The flip-chip chip-scale package structure of claim 1, further comprising a metal cap disposed on said first end of said metal ribbon.

6. The flip-chip chip-scale package structure of claim 5, wherein said metal cap is bonded to said first end of said metal ribbon by way of metal diffusion bonding.

7. The flip-chip chip-scale package structure of claim 5, wherein said metal cap is bonded to said first end of said metal ribbon by way of soldering.

8. The flip-chip chip-scale package structure of claim 1, wherein said plurality of bumps is a plurality of metal ball bumps or a plurality of metal block bumps formed by way of metal diffusion bonding and without under bump metallurgy (UBM) between said plurality of bumps and said plurality of bond pads.

9. A chip package structure, comprising:
a substrate;
a die including a first surface and a second surface, a plurality of bond pads formed on said second surface of said die and a plurality of bumps formed between said plurality of bond pads and the substrate;
a back-side metal formed on said first surface of said die;
a ribbon including a first end and a second end, wherein said first end is electrically and thermally coupled to said-back side metal, and said second end is electrically and thermally coupled to said substrate; and
a cap thermally coupled to said first end of said ribbon.

10. The chip package structure of claim 9, wherein said ribbon is a metal ribbon and said first end of said metal ribbon is electrically and thermally coupled to said back-side metal by way of metal diffusion bonding.

11. The chip package structure of claim 9, wherein said cap is a metal cap and said metal cap is thermally coupled to said first end of said ribbon by way of metal diffusion bonding.

12. The chip package structure of claim 9, wherein said cap is a metal cap and said metal cap is thermally coupled to said first end of said ribbon by way of soldering.

13. The chip package structure of claim 13, wherein said plurality of bumps is a plurality of metal ball bumps or a plurality of metal block bumps formed by way of metal diffusion bonding and without under bump metallurgy (UBM) between said plurality of bumps and said plurality of bond pads.
